(19) United States
(12) Patent Application Publication
(10) Pub. No.: US 2014/0124923 A1
(43) Pub. Date: May 8, 2014

(54) SEMICONDUCTOR DEVICES HAVING A STAGGERED PAD WIRING STRUCTURE

(71) Applicant: SAMSUNG ELECTRONICS CO., LTD., Suwon-si (KR)

(72) Inventor: Young-Jin CHO, Osan-si (KR)

(73) Assignee: SAMSUNG ELECTRONICS CO., LTD., Suwon-si (KR)

(21) Appl. No.: 14/072,993

(22) Filed: Nov. 6, 2013

(30) Foreign Application Priority Data
Nov. 8, 2012 (KR) 10-2012-0126154

(51) Int. Cl. H01L 23/498; H01L 27/12

(52) U.S. Cl. CPC H01L 23/49838; H01L 27/124
USPC 257/737

(57) ABSTRACT

A semiconductor device includes a plurality of first metal wirings of first to n-th layers disposed on a substrate, and a plurality of pad wirings disposed on the first metal wirings and including a metal material of an n+1-th layer. The pad wirings are disposed in a staggered shape in a first direction and have a rectangular shape lengthily extending in a second direction. A plurality of additional wirings are disposed in an additional wiring region in the first direction and include the metal material of the n+1-th layer. The additional wiring region is disposed between the pad wirings. A plurality of pads may contact an upper surface of the pad wirings. The pads have a rectangular shape having a first width in the first direction and a first length greater than the first width in the second direction.

### CROSS-REFERENCE TO RELATED APPLICATION

This application claims priority under 35 USC §119 to Korean Patent Application No. 10-2012-0126154, filed on Nov. 8, 2012, the disclosure of which is hereby incorporated by reference herein in its entirety.

### TECHNICAL FIELD

Example embodiments relate to semiconductor devices, and more particularly to display integrated circuit devices including a wiring structure having low resistance.

### DISCUSSION OF THE RELATED ART

A display driver integrated circuit (DDI) device is a semiconductor device for controlling a display module. That is, driving signals and data signals may be applied to a display panel through the DDI to display an image or a moving image. A mobile DDI used in a device such as a mobile phone may include a source driver IC and a gate driver IC. Recently, devices such as, for example, various driver ICs, and timing controllers, have been stacked to obtain one chip. As the DDI may be formed at one side of a display panel, a side facing the display panel may be formed in a rectangular region having a relatively longitudinal shape. As described above, a wiring having low resistance is desired to be formed in a narrow area considering the properties of the DDI having the rectangular shape and having a pair of long sides. Thus, the wiring having low resistance may be formed in a narrow area considering the rectangular shape of the DDI having a pair of long sides.

### SUMMARY

Example embodiments provide a semiconductor device including a wiring structure having low resistance.

Example embodiments provide a display driver integrated circuit including a wiring structure having low resistance.

According to an example embodiment, a semiconductor device includes a plurality of first metal wirings of first to n-th layers disposed on a substrate, and a plurality of pad wirings disposed on the first metal wirings and include a metal material of an n+1-th layer. The pad wirings are disposed in a staggered shape in a first direction and have a rectangular shape lengthily extending in a second direction perpendicular to the first direction. A plurality of additional wirings are disposed in an additional wiring region in the first direction and include the metal material of the n+1-th layer. The additional wiring region is disposed between the pad wirings. A plurality of pads contact an upper surface of the pad wirings. The pads have a rectangular shape having a first width in the first direction and a first length greater than the first width in the second direction.

In an embodiment, bumps covering an upper surface of the pads and electrically coupled to the pad wirings may be further included in the semiconductor device.

Each of the bumps may have a shape covering at least of a portion of one of the pad wirings and an upper portion of at least of a portion of the additional wirings disposed adjacent to one of the pad wirings.

The pad wirings may have a second width, the second width being constant and greater than the first width of the pads in the first direction. Lengths of the pad wirings neighboring in the first direction may be different from each other in the second direction.

A first pad and a second pad, disposed on the pad wirings neighboring in the first direction may be disposed in a staggered shape.

A plurality of switching devices disposed on an upper surface of an edge portion of the substrate in parallel to the first direction may be further included in the semiconductor device. The first metal wirings may be respectively connected with the switching devices.

The semiconductor device may further include a first circuit part disposed adjacent to the switching device. The first circuit part may include a plurality of second metal wirings of the first to n-th layers. The semiconductor device may further include a second circuit part disposed adjacent to the first circuit part. The second circuit part may include a plurality of third metal wirings of the first to n-th layers.

The additional wirings may have a plurality of line shapes extending from the additional wiring region, bent over to the first and second circuit parts, and extending over from the first and second circuit parts to the additional wiring region.

The additional wirings may include a plurality of via contacts making an electric connection with the second metal wirings and disposed in the additional wiring region, and a plurality of wiring lines contacting the via contacts.

According to an example embodiment, a display driver integrated circuit includes a plurality of switching devices disposed on a surface of a pad region at an edge portion of a substrate in parallel to a first direction, and a plurality of first metal wirings of first to n-th layers. The first metal wirings respectively are connected with the switching devices. An amp part is disposed in an amp region of the substrate. The amp part includes a plurality of second metal wirings of the first to n-th layers. A decoder part is disposed in a decoder region of the substrate. The decoder part includes a plurality of third metal wirings of the first to n-th layers. A plurality of pad wirings are disposed on the first metal wirings including a metal material of an n+1-th layer. The pad wirings are disposed in a staggered shape in the first direction. The pad wirings have a rectangular shape extending lengthily in a second direction perpendicular to the first direction. A plurality of additional wirings are disposed in an additional wiring region and include the metal material of the n+1-th layer, and the additional wiring region is disposed between the pad wirings. The additional wirings are connected with the second metal wiring in the amp part. A plurality of pads contact an upper surface of the pad wirings. The pads have a rectangular shape having a first width in the first direction and a first length greater than the first width in the second direction.

A plurality of bumps covering an upper surface of the pads and electrically coupled to the pad wirings may be further included in the display driver integrated circuit.

Each of the bumps may have a shape covering at least of a portion of one of the pad wiring and an upper portion of at least of a portion of the additional wirings disposed adjacent to one of the pad wiring.

The additional wirings may have a plurality of line shapes extending from the additional wiring region, bent over to the amp part and the decoder part, and extending over from the amp part and the decoder part to the additional wiring region.

The additional wirings may include a plurality of via contacts electrically coupled to the second metal wirings and disposed in the additional wiring region, and wiring lines contacting the via contacts.

In an example embodiment, a display driver integrated circuit is provided. The display driver integrated circuit includes a plurality of switching devices disposed on a surface of a pad region at an edge portion of a substrate in parallel to a first direction, a plurality of first metal wirings of first to n-th layers, in which the first metal wirings are respectively connected with the switching devices, an amp part disposed in an amp region of the substrate, in which the amp part including a plurality of second metal wirings of the first to n-th layers, and a decoder part disposed in a decoder region of the substrate, in which the decoder part includes a plurality of third metal wirings of the first to n-th layers.

In addition, the display driver integrated circuit further includes a plurality of first pad wirings and a plurality of second pad wirings disposed on the first metal wirings and including a metal material of an n+1-th layer, and in which the first and second pad wirings are disposed in parallel in the first direction, the first and second pad wirings are disposed in a staggered shape in the first direction and the first and second pad wirings have a rectangular shape having sides longer in a second direction perpendicular to the first direction than in the first direction.

The display driver integrated circuit further includes a passivation layer including an insulating material and is disposed on an upper surface of the first and second pad wirings, a plurality of bump metal lines disposed in an additional wiring region in the first direction and includes the metal material of the n+1-th layer, and in which the additional wiring region is disposed between the first and second pad wirings and between the second pad wirings. The bump metal lines are disposed only in an area of the additional wiring region located between the second pad wirings and the decoder part.

Furthermore, the display driver integrated circuit further includes a plurality of via contacts disposed in the additional wiring region, and in which the bump metal lines are connected with the second metal wirings in the amp part by the via contacts, a plurality of first pads and a plurality of second pads contacting an upper surface of the first and second pad wirings, respectively through pad portion openings in the passivation layer, in which the first and second pads are disposed in a staggered shape in the first direction, and in which the first and second pads have a rectangular shape have sides longer in the second direction than in the first direction and a plurality of first bumps and a plurality of second bumps disposed on an upper surface of the passivation layer in a staggered state and contacting the first pads and the second pads, respectively. The first and second bumps electrically contact the first and second pad wirings through the first and second pads, respectively.

As described above, a semiconductor device in accordance with example embodiments may include an additional wiring region between top metal wirings being connected with pads. As the additional wirings may be provided in the additional wiring region, wirings having low resistance may be formed in narrow horizontal and vertical regions without enlarging the horizontal and vertical regions. Thus, a highly integrated semiconductor device including a minute wiring structure may be manufactured.

### BRIEF DESCRIPTION OF THE DRAWINGS

Illustrative, non-limiting example embodiments will be more clearly understood from the following detailed description taken in conjunction with the accompanying drawings.

FIG. 1 is a planar block diagram illustrating a semiconductor device in accordance with an example embodiment of the inventive concept.

FIG. 2 is a block diagram illustrating detailed elements of a source driver illustrated in FIG. 1.

FIG. 3 is a layout illustrating a wiring portion for pad in a semiconductor device in accordance with an example embodiment of the inventive concept.

FIG. 4 is a layout illustrating an additional wiring region in FIG. 3.

FIG. 5 is a cross-sectional view taken along a line I-I′of FIG. 3.

FIG. 6 is a layout illustrating a pad wiring portion in a semiconductor device in accordance with an example embodiment of the inventive concept.

FIG. 7 is a diagram illustrating a mobile display device including a DDI in accordance with an example embodiment of the inventive concept.

FIG. 8 is a diagram illustrating a display device in accordance with an example embodiment of the inventive concept.

FIG. 9 is a block diagram illustrating a system including a display device in accordance with an example embodiment of the inventive concept.

### DETAILED DESCRIPTION OF EXAMPLE EMBODIMENTS

Various example embodiments will be described more fully hereinafter with reference to the accompanying drawings, in which example embodiments are shown. Example embodiments of the present inventive concept may, however, be embodied in many different forms and should not be construed as limited to example embodiments set forth herein. In the drawings, the sizes and relative sizes of layers and regions may be exaggerated for clarity. Like numerals refer to like elements throughout.

As used herein, the term “and/or” includes any and all combinations of one or more of the associated listed items.

It will be understood that when an element is referred to as being “connected” or “coupled” to another element, it can be directly connected or coupled to the other element or intervening elements may be present.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved.

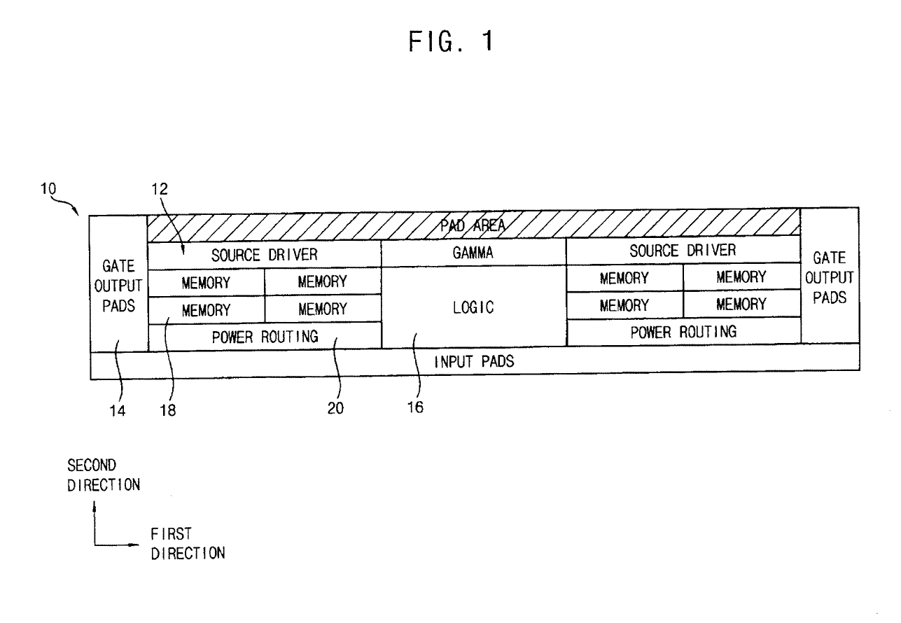

FIG. 1 is a planar block diagram illustrating a semiconductor device according to an example embodiment.

The semiconductor device illustrated in FIG. 1 is a DDI for displaying a two-dimensional or a three-dimensional image corresponding to inputted image data to a display panel by driving a display panel based on the inputted image data. Hereinafter, the DDI is explained as an example embodiment. However, the semiconductor device in accordance with example embodiments may include various semiconductor devices having a staggered pad wiring structure.

Referring to FIG. 1, a DDI device 10 may include, for example, a source driver 12, a gate driver 14, a logic part 16, a power routing 20, a memory 18, etc.

The source driver 12 may apply a signal voltage to each pixel of the display panel. When the gate driver 14 applies a pulse signal to the gate of the display panel to make a turn-on state, the source driver 12 may drive each data line (that is, channel) in the display panel through a channel driver to apply a voltage necessary for the pixels on the display panel.

As the number of the data lines controlling each pixel in the display panel increases, the number of each channel driver included in the source driver 12 may be also increased.

As illustrated in FIG. 1, the source driver 12 may be formed, for example, in a rectangular region having a pair of very long sides in parallel to the display panel and a pair of very short sides which are vertical to the display panel. Hereinafter, the extended direction of the long sides of the source driver may be called as a first direction, and the extended direction of the short sides of the source driver may be called as a second direction.

Because of the shape of the source driver 12, the length of the wiring lines applying the voltage to each of the channel drivers may be largely lengthened in the first direction. Thus, the resistance of the wiring lines may be increased. In addition, as the number of the channel driver increases, the application of the voltage of target level by each channel through the wiring line may be difficult. When the number of the wiring lines is increased to decrease the resistance of the wiring lines, a region for forming the wiring lines may be necessary. Thus, a horizontal area and a vertical area occupying the source driver may be undesirably increased.

The gate driver 14 may generate a voltage to be applied to the gate electrode corresponding to each pixel of the display panel and to apply the voltage to gate wirings. The gate wirings for applying a turn-on signal to the gate may be selected, for example, one by one and the generated voltage may be applied to the gate wirings. The gate driver 14 may be designed as a circuit having a plurality of output terminals. Generally, the number of the output terminal may be determined by, for example, the resolution of the display panel.

The memory 18 may be a memory device storing image data inputted to the source driver 12 and the memory 18 may include, for example, a random access memory (RAM). For example, the memory 18 may be also called a graphic RAM or a GRAM and may have a function of a read operation and a write operation by a memory interface and a data transmission function to the source driver 12. The size of the memory 18 may vary depending on, for example, the resolution of the display and the number of the expressible colors.

Even though not particularly illustrated in FIG. 1, the DDI 10 may further include, for example, a DC/DC converter, a timing controller, a gray scale voltage generating circuit and a global voltage generating circuit, etc.

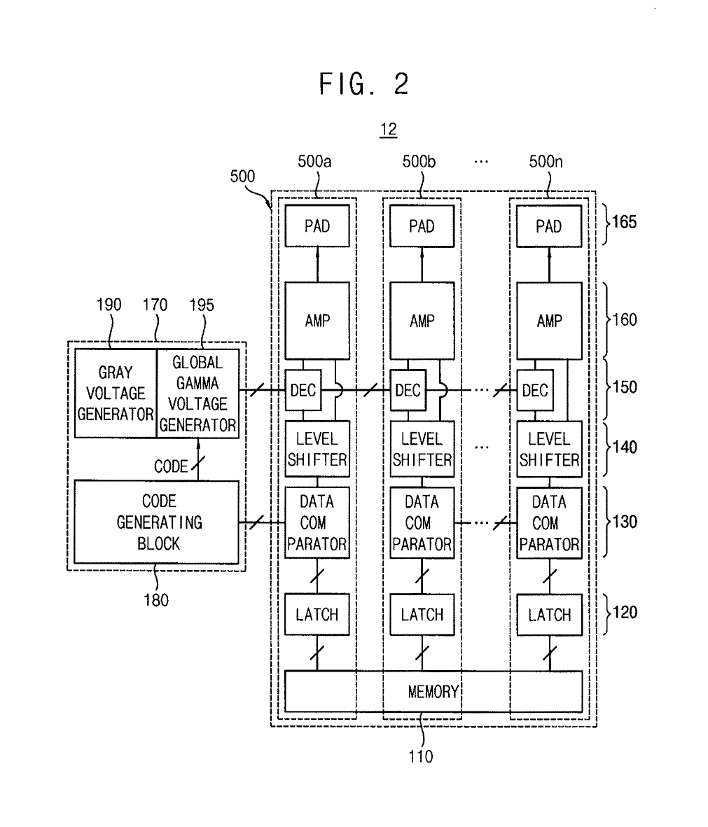

FIG. 2 is a block diagram illustrating detailed elements of the source driver illustrated in FIG. 1.

Referring to FIG. 2, the source driver 12 may include, for example, a global block 170 and a channel driver part 500. The channel driver part 500 may include, for example, each of channel drivers 500a to 500n.

The global block 170 may generate, for example, a plurality of PWM signals (Track<0:m−1>, m is an integer greater than or equal to 2) and k (an integer greater than or equal to 2) of global gamma voltage signals (A1 to Ak) according to the generated digital code (CODE) based on the power routing. Each of a plurality of the channel may respond to, for example, the plurality of the PWM signals (Track<0:m−1>), k of the global gamma voltage signals (A1 to Ak), and digital image data to drive each of a plurality of the data lines formed on the display panel.

The global block 170 may be, for example, a common block over the whole channels and may include a code generating block 180, a gray voltage generator 190 and a global gamma voltage generator 195.

The channel driver part 500 may include, for example, a memory part 110, a latch part 120, a data comparator 130, a level shifter block 140, a decoder part 150, an amp part 160 and a pad part 165.

In the channel driver part 500, a circuit for driving a data line may be called, for example, channel drivers 500a to 500n. Thus, for example, in the channel driver part 500, the same number of the channel drivers 500a to 500n may be included as the number of the data lines. Each of the channel drivers 500a to 500n may include, for example, circuits for a memory 110, a data latch 120, a data comparator 130, first and second level shifter part 140, a decoder part 150, an amp part 160 and a pad part 165.

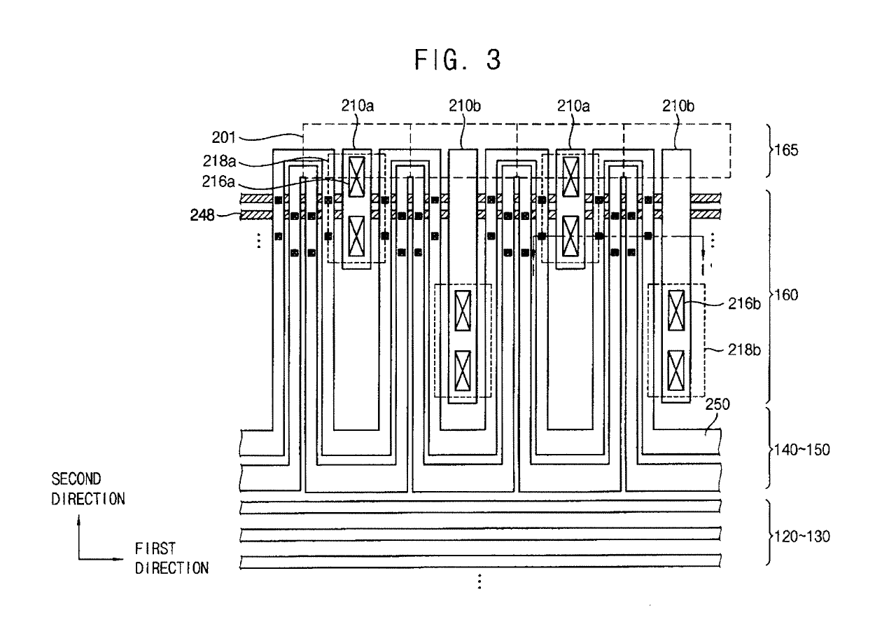

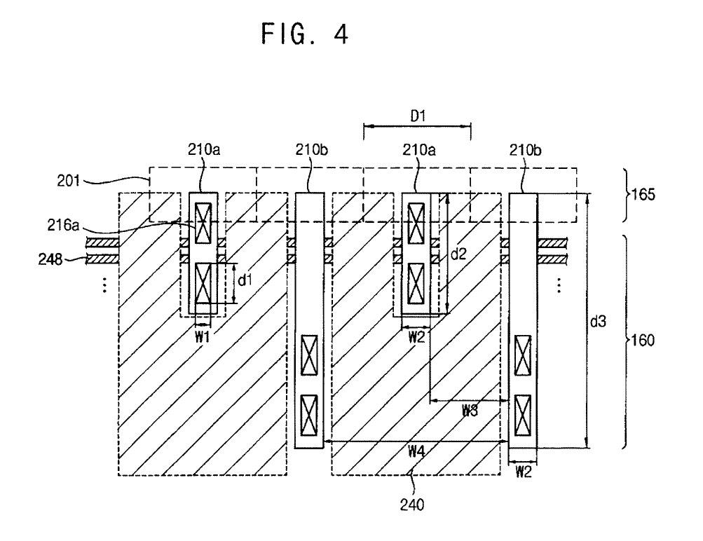

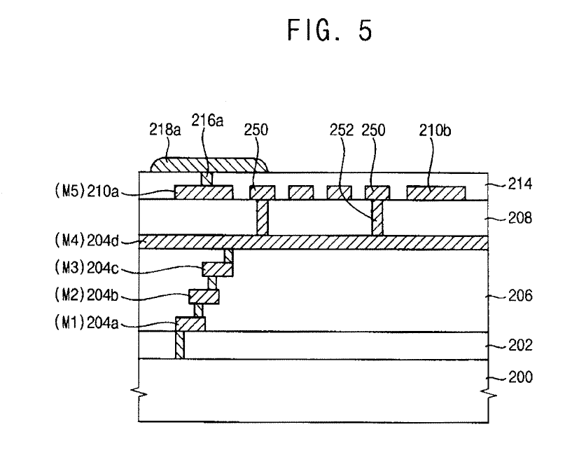

FIG. 3 is a layout illustrating a wiring portion for pad in a semiconductor device in accordance with an embodiment of the inventive concept. FIG. 4 is a layout illustrating an additional wiring region in FIG. 3. FIG. 5 is a cross-sectional view taken along a line I-I′ of FIG. 3.

FIG. 4 is a layout excluding a bump and an additional wiring for illustrating an additional wiring region.

FIG. 3 is a portion of a channel driver part in the source driver in FIG. 2. Referring to FIG. 3, each of the constituting elements included in the channel driver part 500 in the source driver 12 may be disposed on, for example, the substrate. The pad part 165 may be provided, for example, at the edge portion of the substrate, and the amp part 160, the decoder part 150, the level shifter part 140, the data comparator 130, the data latch 120 and the memory 110 may be provided, for example, one by one from the pad part 165 to a center portion of the substrate.

As the pad part 165 may be disposed at the edge portion of the source driver 12, the pad part 165 may be disposed at, for example, the edge portion of the DDI. Each pad part 165 may include, for example, underlying wirings including a switching device 201 and contacts and lines contacting the switching device 201, and pad wirings 210a and 210b making a connection with the underlying wiring. As the top connecting wirings may be wirings for making a connection with pads at the upper portion, the top connecting wirings may be, for example, called pad wirings hereinafter. In addition, for example, pads 216a and 216b contacting a portion of the upper surface of the pad wirings 210a and 210b, and bumps 218a and 218b electrically contacting the pad wirings 210a and 210b through the pads 216a and 216b may be provided.

The switching device 201 may include, for example, a PN diode or a CMOS transistor. As illustrated in the drawing, each switching device 201 may have, for example, a shape arranged at the edge portion of the substrate in parallel in the first direction. Each of the switching devices 201 may be provided on, for example, the surface of the substrate. Thus, the underlying wirings connected with the switching devices 201 may have, for example, a vertically stacked shape from the surface of the substrate to the bottom surface of the top pad wiring.

The pad wirings 210a and 210b may be electrically coupled to the switching devices 201. For example, one of the pad wirings 210a and 210b may be electrically connected with one of the switching devices 201, respectively.

For forming a semiconductor device, metal wirings obtained by, for example, stacking a multi layer may be used as each of connecting wirings. For example, as the pad wirings 210a and 210b may be electrically connected with the pads and the bumps to input/output signals from/to exterior, the pad wirings 210a and 210b may include a top metal disposed at the uppermost portion. For example, referring to FIG. 5, when the DDI includes stacked 5 layers of metal wirings 204a, 204b, 204c, 204d, 210a, the pad wirings 210a and 210b may include a metal material 210a(M5) positioned at the uppermost fifth layer. The metal wirings 204a, 204b, 204c, 204d, 210a may be formed on inter metal dielectric layers 202, 206, 208.

Referring to FIGS. 4 and 5, as one of the pad wirings 210a and 210b may be electrically connected with one switching device 201, electric signals may be inputted or outputted through the pad wirings 210a and 210b to the switching devices 201. Thus, the pad wirings 210a and 210b may be disposed at, for example, the edge portion of the substrate 200 in parallel to the first direction. That is, the pad wirings 210a and 210b may be disposed, for example, in parallel along the long sides of the substrate 200. In addition, the pad wirings 210a and 210b may have, for example, a line shape extended from the edge portion of the substrate 200 toward a center portion of the substrate 200.

To prevent a bridge defect from occurring as a result of the pad wirings electrically contacting pad wirings with each other, edge portions of the pad wirings 210a and 210b may be formed, for example, so as to be positioned in a staggered shape in the first direction from a plan view. In other words, the neighboring pad wirings 210a and 210b may be formed, for example, to have different lengths in the second direction. Hereinafter, for example, the pad wiring having a relatively small length will be called as a first pad wiring, and the pad wiring having a relatively large length will be called as a second pad wiring.

For example, wirings being connected with the switching devices 201 at odd numbered positions among the switching devices 201 arranged in the first direction may be the first pad wirings 210a. The first pad wiring 210a may have, for example, a constant width without being changed according to the portions. The first pad wiring 210a may include, for example, a first pad forming region for forming a pad for connecting with the bump.

In addition, wirings being connected with the switching devices 201 at, for example, even numbered positions among the switching devices arranged in the first direction may be the second pad wirings 210b. The second pad wirings 210b may include, for example, an extending region and a second pad forming region. The extending region may be, for example, a region excluding the pad and the second pad forming region may be a region for forming the pad. The second pad wiring 210b may have, for example, a constant width without being changed according to the parts. That is, the extending region and the second pad forming region may have, for example, the same width.

In the above description, the first pad wirings 210a may be provided at the odd numbered positions and the second pad wirings 210b longer than the first pad wirings 210a may be provided at the even numbered positions. However, alternatively in an example embodiment, the second pad wirings may be provided at the odd numbered positions and the first pad wirings 210a shorter than the second pad wirings 210b may be provided at the even numbered positions, without limitation.

The first pad wiring 210a may have, for example, a line shape having a second width W2 in the first direction and a second length d2 in the second direction. The second length d2 may be, for example, larger than the second width W2. Thus, the first pad wiring 210a may have, for example, a rectangular shape having a line shape in the second direction.

The second pad wiring 210b may have, for example, a line shape having a second width W2 in the first direction and a third length d3 in the second direction. In this case, the third length d3 may be, for example, greater than the second length d2. Thus, the second pad wiring 210b may have, for example, a rectangular shape having the same width as the first pad wiring 210a and larger length than the first pad wiring 210a.

As the second width of the first and second pad wirings 210a and 210b is decreased, an additional wiring region 240 between the first and second pad wirings 210a and 210b may be increased. Thus, the second width of the first and second pad wirings 210a and 210b may be decreased. However, as pads 216a and 216b may be formed on the first and second pad wirings 210a and 210b, as illustrated in the drawings, the first and second pad wirings 210a and 210b may not have a smaller width than a first width W1 of the pads 216a and 216b. That is, the minimum width of the first and second wirings for pad 210a and 210b may be, for example, greater than or the same as the first width W1 of the pads 216a and 216b. As described above, the second width W2 of the first and second pad wirings 210a and 210b may be determined by the first width W1 which is the width of the pads 216a and 216b contacting the upper portion of the first and second pad wirings 210a and 210b.

When the first width W1 is decreased, the second width W2 may be also decreased. For example, the second width W2 may be greater by a certain overlapped margin to both sides of the first width W1. For example, the second width W2 may be greater by the overlapped margin of about 0.3 to about 5 μm to both sides of the first width W1.

Even though an explanation may be given hereinafter, the first width W1 of the pads 216a and 216b may be, for example, smaller than the first length of the pads 216a and 216b. The pads 216a and 216b may have, for example, a rectangular shape having long sides in the second direction. As described above, as the shape of the pads 216a and 216b are rectangular having long sides in the second direction, the first width W1 may be largely decreased. Thus, the second width W2 may be also decreased.

Meanwhile, the second width W2 may have, for example, a smaller width than the width D1 in the first direction of a region occupied by one switching device electrically being connected with the first pad wiring 210a. When the second width W2 of the first pad wiring 210a is decreased very small, the passivation of circuits from electro-static discharge (ESD) may be difficult. Thus, the second width W2 may have enough width for passivating the ESD.

The first and second pad wirings 210a and 210b may have, for example, a shape extended over from the switching device portion at the edge portion of the semiconductor device over to the amp part 160 and the decoder parts 150 in the semiconductor device.

On the upper surface of the first and second pad wirings 210a and 210b, a passivation layer 214 of an insulating material may be provided. For example, at a portion of a passivation layer 214 formed on the upper surface of the first and second pad wirings 210a and 210b, pad opening portions having a hole shape may be provided. In the pad opening portions, the pads 216a and 216b may be provided. Hereinafter, a pad contacting the upper surface of the first pad wiring 210a may be called, for example, a first pad 216a, and a pad contacting the upper surface of the second pad wiring 210b may be called as a second pad 216b. The first and second pads 216a and 216b may include, for example, the same metal material as the bump.

On the upper surface of each of the first pad wirings 210a, one or more first pads 216a may be provided. From the plan view, the first pad 216a may have, for example, a rectangular shape having long sides in the second direction. For example, from the plan view, the first pad 216a may have a rectangular shape having a first width W1 in the first direction and a first length d1 greater than the first width W1 in the second direction. The first width W1 may be, for example, smaller than the second width W2.

On the upper surface of each of the second pad wirings 210b, one or more second pads 216b may be provided. From the plan view, the second pad 216b may have, for example, a rectangular shape having long sides in the second direction. For example, from the plan view, the second pad 216b may have a rectangular shape having a first width W1 in the first direction and a length greater than the first width W1 in the second direction. As described above, the lengths of the first and second pads 216a and 216b may be the same or different from each other. That is, the first and second pads 216a and 216b may have, for example, the same size or a different size as each other.

The first and second pads 216a and 216b may be disposed, for example, in a staggered shape without being overlapped in the first direction. In addition, the longitudinal direction extended from each of the first and second pads 216a and 216b may be, for example, the same as the longitudinal direction extended from the underlying first and second pad wirings 210a and 210b.

As illustrated in the drawing, the first and second pads 216a and 216b may have, for example, a rectangular shape having long sides in the second direction. Thus, the first and second pads 216a and 216b may have, for example, an even smaller width when compared with pads having a common structure of a rectangular shape having long sides in the first direction. For example, the first and second pads 216a and 216b in accordance with example embodiments may have a 90°-rotated shape of the pads having the common structure.

As described above, the line width and the shape of the first and second pad wirings 210a and 210b formed, for example, under the first and second pads 216a and 216b, respectively, according to the shape of the first and second pads 216a and 216b may be determined. That is, through forming the first and second pads 216a and 216b having very small first width, the second width of the first and second pad wirings 210a and 210b may be also decreased.

For example, on the upper surface of the passivation layer 214, bumps 218a and 218b respective contacting the first and second pads 216a and 216b may be provided. The bumps 218a and 218b may include, for example, a first bump 218a contacting the first pad 216a and a second bump 218b contacting the second pad 216b. On one of the first pad wirings 210a, for example, at least one of the first bumps 218a may be provided. In addition, on one of the second pad wirings 210b, for example, at least one of the second bumps 218b (see FIG. 3) may be provided.

The first and second bumps 218a and 218b may be disposed in, for example, a staggered state in the first direction.

The first bump 218a may be formed on, for example, a wide area deviated from the upper portion of the first pad wiring 210a. Thus, the first bump 218a may be positioned over, for example, the first pad wiring 210a and over a bump metal line 250 which is an additional wiring disposed around the first pad wiring 210a. The second bump 218b may be formed, for example, on a wide area deviated from the upper portion of the second pad wiring 210b. Accordingly, the second bump 218b may be positioned on, for example, the second pad wiring 210b and on the bump metal line 250 which is an additional wiring disposed around the second pad wiring 210b.

Generally, when no metal pattern is provided between the first and second pad wirings, a bump positioned at the position deviated from the upper portion of the pad wiring may have a structure excluding an underlying metal pattern and including only a passivation layer, and may have an unstable structure. Thus, dummy metal patterns substantially not used for a circuit operation may be commonly formed between the first and second pad wirings.

For example, in an example embodiment, between the first and second pad wirings 210a and 210b, the bump metal line 250 which may be an additive wiring substantially used for the circuit operation may be disposed. As the bump metal line 250 may be disposed under the first and second bumps 218a and 218b, extra dummy metal patterns may not be necessary. In addition, as the bump metal line 250 may be provided, the first and second bumps 218a and 218b may have a quite stable structure.

Two neighboring first and second pad wirings 210a and 210b may be, for example, spaced apart from each other by a third width W3 in the first direction. In addition, the neighboring second pad wirings 210b may be, for example, spaced apart from each other by a fourth width W4 in the first direction.

As described above, as the shape of the pad is changed so as to have a rectangular shape having long sides in the second direction, the underlying first and second pad wirings 210a and 210b may be extended with a uniform width and have a rectangular shape having long sides in the second direction. Through the change of the pad shape, the first width W1 of the first and second pads 216a and 216b may be decreased and so, the second width W2 of the first and second pad wirings 210a and 210b may be decreased. Thus, the third width W3 between the first and second pad wirings 210a and 210b, and the fourth width W4 between the second pad wirings 210b may be sufficiently and widely secured.

An additional wiring region 240 may be, for example, provided between the first and second pad wirings 210a and 210b, and between the second pad wirings 210b. The additional wiring region 240 may include, for example, the upper portion of the switching device 201. The area of the additional wiring region 240 may be, for example, broadened according to the decrease of the width W1 of the first and second pads 216a and 216b.

In the additional wiring region 240, metal wirings 250 including, for example, a top metal may be additionally provided. The metal wiring 250 provided in the additional wiring region 240 may be, for example, being electrically coupled to the switching devices with the circuits disposed in the substrate.

Hereinafter, a metal wiring which may be included in the additional wiring region is explained in detail.

Referring to FIG. 3 again, provided are, for example, the amp part 160 and the decoder part 150 in the substrate 200 from the switching devices 201.

The circuits constituting the amp part 160 may include, for example, underlying metal wirings excluding the top metal and the bump metal line 250 including the top metal material.

The bump metal line 250 may include, for example, the same metal material as the first and second pad wirings 210a and 210b. For example, when five layers in total of the metal wirings are included in the semiconductor device, the bump metal line 250 may be formed by using the fifth metal material (M5). As the bump metal line 250 may be formed by, for example, using the top metal material having low resistance, a power application may become relatively easy, and the bump metal line 250 may have low resistance. The bump metal line 250 may be connected with underlying amp power lines by using, for example, via contacts 252. Thus, the bump metal line 250 may be provided as an additional power applying line. In addition, as the bump metal line 250 may have a structure making a connection with the underlying amp power lines in parallel, a power wiring having low resistance may be accomplished.

The bump metal line 250 may be provided as, for example, at least a metal wiring positioned in the additional wiring region 240. As illustrated in the drawing, the bump metal line 250 may be positioned on, for example, the additional wiring region 240 (see FIG. 4) and the decoder part 150. The decoder part 150 may be disposed, for example, in parallel with the level shifter part 140 in the first direction. In this case, the bump metal line 250 may be positioned on, for example, the additional wiring region 240, the decoder part 150 and the level shifter part 140.

The via contacts 252 for connecting the bump metal line 250 and the underlying wiring lines 248 may be positioned in, for example, the additional wiring region 240. That is, the via contacts 252 may not be provided on the decoder part 150 and the level shifter part 140. Thus, even though the bump metal line 250 may be positioned on the circuits constituting the decoder part 150 and the level shifter part 140, the layout and the constitution of the circuits constituting the decoder part 150 and the level shifter part 140 may not be affected.

As described above, the bump metal line 250 may be provided in, for example, the additional wiring region 240 between the first and second pad wirings 210a and 210b. Through providing the bump metal line 250, the total resistance of the wiring lines for applying a voltage to the amp part 160 may be decreased. Thus, a target power may be applied to the amp part 160.

The circuits constituting the decoder part 150 may, for example, not include the top metal, and the circuits may be constituted by using the metal wiring positioned under the top metal. For example, when five layers in total of the metal wirings are included in the semiconductor device, the metal wiring constituting the decoder part 150 may be formed by using the first to fourth metal materials M1 to M4 under the fifth metal material. That is, the metal wiring constituting the decoder part 150 may be positioned under the first and second pad wirings 210a and 210b. The metal wiring included in the decoder part 150 may include, for example, a plurality of densely arranged metal lines having minute line width for power routing of the decoder.

When the metal wiring is formed by additionally using the top metal, a region for connecting the decoder metal lines and the top metal wiring may be additionally required, and horizontal and vertical regions for forming a semiconductor device may be increased. Differently, when the metal wiring of the decoder part 150 may be formed by additionally stacking the metal wiring, the vertical region and the horizontal region for forming the semiconductor device may be increased. Thus, the metal wiring of the decoder part 150 may be formed by using, for example, the metals under the top metal.

As described above, as the circuit forming the decoder part 150 may exclude the top metal, the bump metal line 250 may have an extended shape to the upper portion of the decoder part 150.

As illustrated in the drawing, the bump metal line 250 may have, for example, a line shape extended from the additional wiring region 240, bent over to the decoder part 150, and then, extended over from the decoder part 150 to the additional wiring region 240. The bump metal line 250 may include, for example, one line or a plurality of lines. However, the shape of the bump metal line 250 may not be limited to the shape.

As described above, by providing the bump metal line 250 including the top metal, a target power supply to each of the channels of a display panel may be accomplished. For example, it may be necessary that the source driver 12 is provided in a region having long sides in the first direction and short sides in the second direction, and it also may be necessary that the source driver 12 be formed so as to apply power to a very large numbers of the channels. Thus, through providing the source driver 12 with the bump metal line 250, the performance of the source driver 12 may be increased.

In addition, as the bump metal line 250 may be provided on the additional wiring region 240 between the pad wirings 210a and 210b and the decoder part 150, additional horizontal region and additional vertical region for forming the bump metal line 250 may not be necessary. Thus, a wiring for applying a power, having low resistance may be provided in a small region without broadening the horizontal and vertical regions.

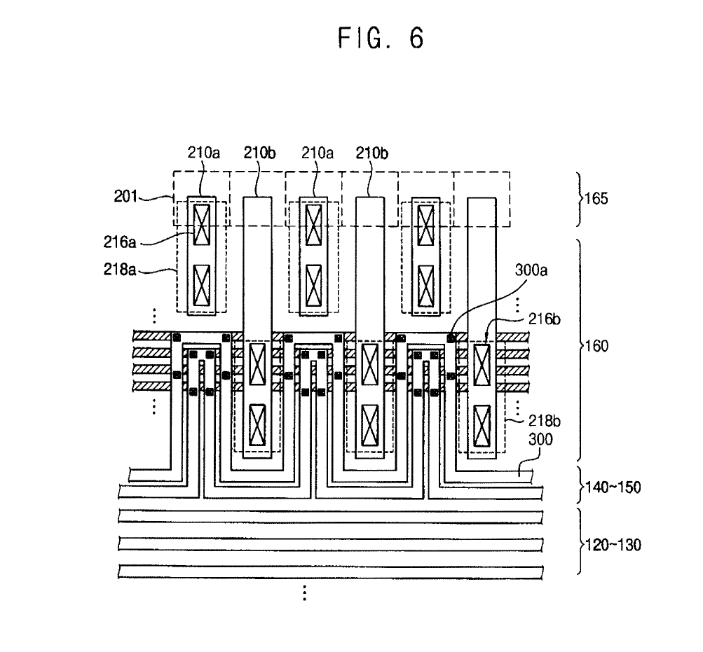

FIG. 6 is a layout illustrating a pad wiring portion in the semiconductor device in accordance with an embodiment of the inventive concept.

The semiconductor device illustrated in FIG. 6 may be the same as that explained referring to FIGS. 1 to 5 except for a bump metal line portion.

Referring to FIG. 6, a bump metal line 300 may be disposed, for example, only on additional wiring regions 240 between second pad wirings 210b and a decoder part 150.

When the distance between switching devices are significantly decreased and the distance between first and second pad wirings 210a and 210b are decreased, the third width between the first and second pad wirings 210a and 210b may be, for example, significantly decreased. In this case, a sufficient space for forming a metal wiring may not be confirmed in a region between the first and second pad wirings 210a and 210b in the additional wiring region 240.

However, even in this case, the fourth width W4 between the second wirings 210b greater than or equal to the width D1 in the first direction occupied by at least one switching device may be confirmed.

As illustrated in the drawing, the bump metal line 300 may be disposed, for example, only on the additional wiring region 240 between the second pad wirings 210b and the decoder part 150 among the additional wiring region 240.

In an example embodiment, the bump metal line 300 may be connected with the amp power lines including underlying metal wirings by using via contacts 300a. The via contacts 300a making a connection with the bump metal line 300 may be positioned in the additional wiring region 240.

As illustrated in the drawing, the bump metal line 300 may have, for example, a plurality of line shapes extended and bent from the additional wiring region 240 over to the decoder part 150, and extended from the decoder part 150 to the additional wiring region 240. However, the shape of the bump metal line 300 may not be limited to the shape.

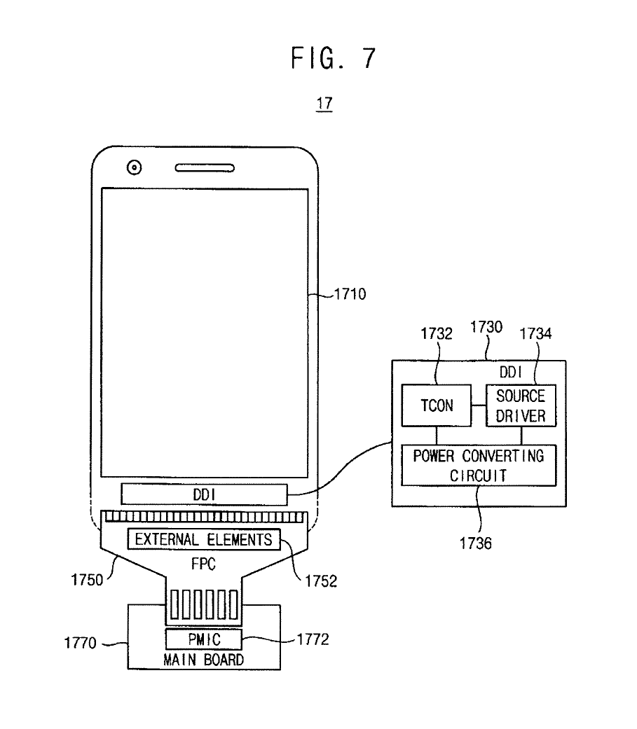

FIG. 7 is a diagram illustrating a mobile display device including a DDI in accordance with an embodiment of the inventive concept.

Referring to FIG. 7, a mobile display device 17 may include, for example, a display panel 1710, a DDI 1730, a flexible printed circuit (FPC) 1750 and a main board 1770.

The DDI 1730 may include, for example, a source driver 1734 for applying a source current to the display panel 1710, a power converting circuit 1736 for applying a source voltage to the source driver 1734, and a timing controller (TCON) 1732 for providing a clock signal to the source driver 1734 and the power converting circuit 1736. The DDI may include, for example, a source driver 1734 having an amp structure including a wiring structure for pad, and an additional wiring structure. As the DDI 1730 may have a wiring of low resistance in the same planar area, a stable power supply may be possible and a high reliability may be obtainable. Thus, the performance of a mobile display device 17 including the DDI 1730 may be increased.

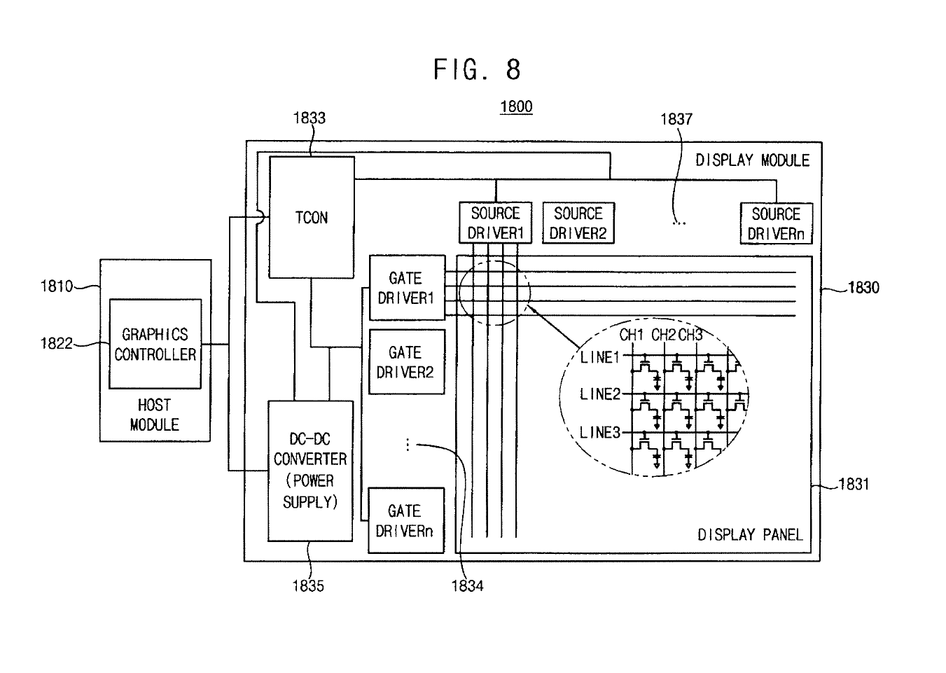

FIG. 8 is a diagram illustrating a display device in accordance with an embodiment of the inventive concept.

Referring to FIG. 8, a display device 1800 may include, for example, a display module 1830 and a host module 1810 for controlling the display module 1830.

The host module 1810 may include, for example, a graphics controller 1822.

The display module 1830 may include, for example, a display panel 1831, a timing controller (TCON) 1833, a DC-DC converter 1835, a source driver 1837 and a gate driver 1834. The display panel 1831 may include, for example, a plurality of gate lines arranged in the first direction and a plurality of data lines arranged in the second direction. In this case, the second direction may be, for example, perpendicular to the first direction. The display panel 1831 may include, for example, a plurality of pixels. In an example embodiment, the pluralities of the pixels may be connected to the pluralities of the gate lines and the pluralities of the data lines to form a matrix shape.

The gate driver 1834 may, for example, apply gate signals to the pluralities of the gate lines one by one during each frame. The source driver 1837 may, for example, apply data signals including information on colors to the pluralities of the data lines. The pluralities of the pixels, for example, may receive the gate signals from the gate driver 1834, may be driven, and may receive the data signals from the source driver 1837 to display corresponding images. The data signals may be a current shape, and the source driver 1837 may control the amount of the current to control the amount of RGB signals. The source driver 1837 may include, for example, the same structure as the amp structure including the wiring structure for pad and the additional wiring structure.

Recently, as the resolution and the size of a display panel increase, power load supplied by the source driver 1837 may be increased. Thus, the source driver 1837 may be necessary to supply a high power. As the source driver in accordance with example embodiments may have a wiring having low resistance, a stable power supply may be possible.

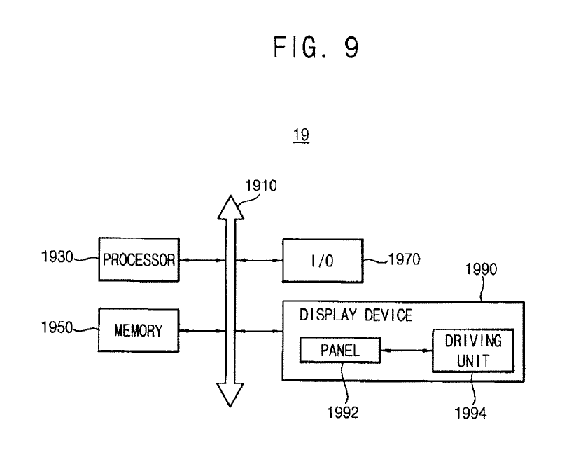

FIG. 9 is a block diagram illustrating a system including a display device in accordance with an example of the inventive concept.

Referring to FIG. 9, a system 19 may include, for example, a processor 1930, a memory device 1950, an input/output apparatus 1970 and a display device 1990.

The processor 1930 may execute various computing functions such as, for example, executing specific software conducting specific calculations or tasks. For example, the processor 1930 may be a microprocessor or a central processing unit (CPU). The processor 1930 may be connected to the memory device 1950 through, for example, a bus 1910. The processor 1930 may be connected to the memory device 1950 and the display device 1990 through, for example, an address bus, a control bus, a data bus, etc. to execute telecommunication. In an example embodiment, the processor 1930 may be connected to an expansion bus such as, for example, a peripheral component interconnect (PCI) bus. For example, the memory device 1950 may include a volatile memory device such as a dynamic random access memory (DRAM). In addition, the memory device 1950 may include, for example, a static random access memory (SRAM), and a non-volatile memory device such as an erasable programmable read-only memory (EPROM), an electrically erasable programmable read-only memory (EEPROM), a flash memory device, etc. The memory device 1950 may store a software executed by the processor 1930.

The input/output apparatus (I/O) 1970 may be connected to the bus 1910 and may include an input device such as, for example, a keyboard or a mouse, and an output device such as a printer. The processor 1930 may control the operation of the input/output apparatus (I/O) 1970.

The display device 1990 may be connected with the processor 1930 through, for example, the bus 1910. As described above, the display device 1990 may include, for example, the display panel 1992 including the pluralities of the pixels connected to the pluralities of the gate lines and the pluralities of the data lines, and a driving unit 1994 for driving the display panel 1992. The driving unit 1994 may include, for example, a timing controller, a source driver, a gate driver, and a power converting circuit for the display driver.

The display device 1990 may include, for example, the mobile display device 17 illustrated in FIG. 7 or the display device 1800 illustrated in FIG. 8.

For example, the system 19 may be an optional electronic device providing a user with an image through the display device 1990, and including a mobile phone, a smart phone, a television, a personal digital assistant (PDA), an MP3 player, a notebook computer, a desk top computer, a digital camera, etc.

As described above, a semiconductor device having decreased contact resistance may be provided in accordance with example embodiments. The semiconductor device may be used in a memory device such as, for example, a DRAM device.

Having described example embodiments of the inventive concept, it is further noted that it is readily apparent to those of ordinary skill in the art that various modifications may be made without departing from the spirit and scope of the invention which is defined by the metes and bounds of the appended claims.

What is claimed is:

1. A semiconductor device comprising:
a plurality of first metal wirings of first to n-th layers disposed on a substrate;
a plurality of pad wirings disposed on the first metal wirings and including a metal material of an n+1-th layer, the pad wirings being disposed in a staggered shape in a first direction and having a rectangular shape lengthily extending in a second direction perpendicular to the first direction;
a plurality of additional wirings disposed in an additional wiring region in the first direction and including the metal material of the n+1-th layer, the additional wiring region being disposed between the pad wirings; and
a plurality of pads contacting an upper surface of the pad wirings, the pads having a rectangular shape having a first width in the first direction and a first length greater than the first width in the second direction.

2. The semiconductor device of claim 1, further comprising a plurality of bumps covering an upper surface of the pads and being electrically coupled to the pad wirings.

3. The semiconductor device of claim 2, wherein each of the bumps has a shape covering at least of a portion of one of the pad wirings and an upper portion of at least of a portion of the additional wirings disposed adjacent to one of the pad wirings.

4. The semiconductor device of claim 1, wherein the pad wirings have a second width, the second width being constant and greater than the first width of the pads in the first direction, and wherein lengths of the pad wirings neighboring in the first direction being different from each other in the second direction.

5. The semiconductor device of claim 1, wherein a first pad and a second pad, disposed on the pad wirings neighboring in the first direction, are disposed in a staggered shape.

6. The semiconductor device of claim 1, further comprising a plurality of switching devices disposed on an upper surface of an edge portion of the substrate in parallel to the first direction, the first metal wirings being respectively connected with the switching devices.

7. The semiconductor device of claim 6, further comprising:
a first circuit part disposed adjacent to the switching device, the first circuit part including a plurality of second metal wirings of the first to n-th layers; and
a second circuit part disposed adjacent to the first circuit part, the second circuit part including a plurality of third metal wirings of the first to n-th layers.

8. The semiconductor device of claim 7, wherein the additional wirings have a plurality of line shapes extending from the additional wiring region, bent over to the first and second circuit parts, and extending over from the first and second circuit parts to the additional wiring region.

9. The semiconductor device of claim 7, wherein the additional wirings comprise:
a plurality of via contacts making an electric connection with the second metal wirings and disposed in the additional wiring region; and
a plurality of wiring lines contacting the via contacts.

10. A display driver integrated circuit comprising:
a plurality of switching devices disposed on a surface of a pad region at an edge portion of a substrate in parallel to a first direction;
a plurality of first metal wirings of first to n-th layers, the first metal wirings respectively being connected with the switching devices;
an amp part disposed in an amp region of the substrate, the amp part including a plurality of second metal wirings of the first to n-th layers;
a decoder part disposed in a decoder region of the substrate, the decoder part including a plurality of third metal wirings of the first to n-th layers;
a plurality of pad wirings disposed on the first metal wirings and including a metal material of an n+1-th layer, the pad wirings being disposed in a staggered shape in the first direction, the pad wirings having a rectangular shape extending lengthily in a second direction perpendicular to the first direction;
a plurality of additional wirings disposed in an additional wiring region and including the metal material of the n+1-th layer, the additional wiring region being disposed between the pad wirings, the additional wirings being connected with the second metal wiring in the amp part; and
a plurality of pads contacting an upper surface of the pad wirings, the pads having a rectangular shape having a first width in the first direction and a first length greater than the first width in the second direction.

11. The display driver integrated circuit of claim 11, further comprising a plurality of bumps covering an upper surface of the pads and being electrically coupled to the pad wirings.

12. The display driver integrated circuit of claim 11, wherein each of the bumps has a shape covering at least of a portion of one of the pad wirings and an upper portion of at least of a portion of the additional wirings disposed adjacent to one of the pad wirings.

13. The display driver integrated circuit of claim 10, wherein the additional wirings have a plurality of line shapes extending from the additional wiring region, bent over to the amp part and the decoder part, and extending over from the amp part and the decoder part to the additional wiring region.

14. The display driver integrated circuit of claim 13, wherein the additional wirings comprises:
a plurality of via contacts being electrically coupled to the second metal wirings, the via contacts being disposed in the additional wiring region; and
a plurality of wiring lines contacting the via contacts.

15. The display driver integrated circuit of claim 11, wherein the plurality of bumps includes a plurality of first bumps and a plurality of second bumps, wherein the pad wirings include a plurality of first pad wirings and a plurality of second pad wirings disposed on the first metal wirings, wherein the first bumps are disposed over the first pad wirings and the second bumps are disposed over the second pad wirings, and wherein the additional wiring includes a plurality of bump metal lines disposed between the first and second pad wirings and underneath the first and second bumps.

16. The display driver integrated circuit of claim 10, wherein the pad wirings have a line shape extending from an edge portion of the substrate toward a center portion of the substrate.

17. A display driver integrated circuit comprising:
a plurality of switching devices disposed on a surface of a pad region at an edge portion of a substrate in parallel to a first direction;
a plurality of first metal wirings of first to n-th layers, the first metal wirings respectively being connected with the switching devices;
an amp part disposed in an amp region of the substrate, the amp part including a plurality of second metal wirings of the first to n-th layers;
a decoder part disposed in a decoder region of the substrate, the decoder part including a plurality of third metal wirings of the first to n-th layers;
a plurality of first pad wirings and a plurality of second pad wirings disposed on the first metal wirings and including a metal material of an n+1-th layer, the first and second pad wirings being disposed in parallel in the first direction, wherein the first and second pad wirings are disposed in a staggered shape in the first direction and wherein the first and second pad wirings have a rectangular shape having sides longer in a second direction perpendicular to the first direction than in the first direction;
a passivation layer including an insulating material and disposed on an upper surface of the first and second pad wirings;
a plurality of bump metal lines disposed in an additional wiring region in the first direction and including the metal material of the n+1-th layer, the additional wiring region being disposed between the first and second pad wirings and between the second pad wirings, wherein the bump metal lines are disposed only in an area of the additional wiring region located between the second pad wirings and the decoder part;
a plurality of via contacts disposed in the additional wiring region, wherein the bump metal lines being connected with the second metal wirings in the amp part by the via contacts;
a plurality of first pads and a plurality of second pads contacting an upper surface of the first and second pad wirings, respectively through pad portion openings in the passivation layer, wherein the first and second pads are disposed in a staggered shape in the first direction, and wherein the first and second pads have a rectangular shape having sides longer in the second direction than in the first direction; and
a plurality of first bumps and a plurality of second bumps disposed on an upper surface of the passivation layer in a staggered state and contacting the first pads and the second pads, respectively, and wherein the first and second bumps electrically contact the first and second pad wirings through the first and second pads, respectively.

18. The display driver integrated circuit of claim 17, wherein the first and second pads include a same material as the first and second bumps.

19. The display driver integrated circuit of claim 17, wherein the bump metal lines have a plurality of line shapes extending and bending from the additional wiring region over to the decoder part, and extending from the decoder part to the additional wiring region.

20. The display driver integrated circuit of claim 17, wherein the second pad wirings have a length greater than a length of the first pad wirings in the second direction, and wherein the first pad wirings and the second pad wirings have substantially a same width as one another in the first direction.
